(19) United States
(12) Patent Application Publication
(10) Pub. No.: US 2025/0324778 A1
(43) Pub. Date: Oct. 16, 2025

(54) RADIATION POWERED COMPUTE

(71) Applicant: T-Mobile Innovations LLC, Overland Park, KS (US)

(72) Inventor: Jason Riley HOOD, Diamond, WA (US)

(21) Appl. No.: 18/634,866

(22) Filed: Apr. 12, 2024

(51) Int. Cl. H01L 31/115; G01T 1/24; H01L 31/06

(52) U.S. Cl. CPC H10F 30/29; G01T 1/24; H10F 10/10

(57) ABSTRACT

A radiation powered computation apparatus is disclosed. In one aspect, the apparatus includes a radiation source that is configured to emit radiation. The apparatus further includes a first layer that surrounds the radiation source and that includes a first plurality of transistors that are configured to be powered by the radiation. The apparatus further includes a second layer that surrounds the first layer and that includes a plurality of receptors that are configured to convert the radiation to power and a second plurality of transistors that receives the power and that are configured control the first plurality of transistors.

### CROSS-REFERENCE TO RELATED APPLICATION

None

### STATEMENT REGARDING FEDERALLY SPONSORED RESEARCH OR DEVELOPMENT

None

### REFERENCE TO A MICROFICHE APPENDIX

None

### BACKGROUND

Radiation is the emission or transmission of energy in the form of waves or particles through space or a material medium. There are various types of radiation. These types are electromagnetic radiation, particle radiation, acoustic radiation, and gravitational radiation.

A transistor is a semiconductor device used to amplify or switch electrical signals and power. It is composed of semiconductor material and typically has at least three terminals. A voltage or current applied to one pair of the transistor's terminals controls the current through another pair of terminals.

### SUMMARY

An innovative aspect of the subject matter described in this specification may be implemented in an apparatus that includes a radiation source that is configured to emit radiation; a first layer that surrounds the radiation source and that includes a first plurality of transistors that are configured to be powered by the radiation; and a second layer that surrounds the first layer and that includes a plurality of receptors that are configured to convert the radiation to power; and a second plurality of transistors that receives the power and that are configured to control the first plurality of transistors.

Other implementations of this aspect include corresponding systems, methods, and computer programs recorded on computer storage devices, each configured to perform the functions of the apparatus.

An innovative aspect of the subject matter described in this specification may be implemented in methods that include the actions of receiving, by a first plurality of transistors that surround a radiation source, radiation; receiving, by a plurality of receptors that surround the radiation source, the radiation; converting, by the plurality of receptors, the radiation to power; providing, by the plurality of receptors and to a second plurality of transistors, the power; and performing, by the first plurality of transistors, a series of operations in response to control signals from the second plurality of transistors.

Other implementations of this aspect include corresponding systems, apparatus, and computer programs recorded on computer storage devices, each configured to perform the operations of the method.

An innovative aspect of the subject matter described in this specification may be implemented in methods that include the actions of determining a type of radiation emitted by a radiation source and a strength of the radiation emitted by the radiation source; based on the type of the radiation and the strength of the radiation, determining a radius of an orb that surrounds the radiation source and that includes a first plurality of transistors and a second plurality of transistors that are configured to control the first plurality of transistors; and based on the type of the radiation and the strength of the radiation, determining a number of additional orbs that each include an additional radiation source at a center of the orb and that each include a first plurality of additional transistors and a second plurality of additional transistors that are configured to control the first plurality of additional transistors. The first plurality of transistors or the second plurality of transistors are connected to each of the first plurality of additional transistors or the second plurality of additional transistors.

Other implementations of this aspect include corresponding systems, apparatus, and computer programs recorded on computer storage devices, each configured to perform the operations of the method.

### BRIEF DESCRIPTION OF THE DRAWINGS

For a more complete understanding of the present disclosure, reference is now made to the following brief description, taken in connection with the accompanying drawings and detailed description, wherein like reference numerals represent like parts.

FIG. 1 illustrates an example system that is configured to utilize a radiation source to power a group of transistors that surround the radiation source.

FIG. 2 is a flowchart of an example process for utilizing a radiation source to power a group of transistors that surround the radiation source.

FIG. 3 is a flowchart of an example process for determining a number and size of computation orbs to surround radiation sources based on the characteristics of the radiation sources.

FIG. 4 illustrates an example computer system.

### DETAILED DESCRIPTION

It should be understood at the outset that although illustrative implementations of one or more implementations are illustrated below, the disclosed systems and methods may be implemented using any number of techniques, whether currently known or not yet in existence. The disclosure should in no way be limited to the illustrative implementations, drawings, and techniques illustrated below, but may be modified within the scope of the appended claims along with their full scope of equivalents.

Power is a critical aspect of all electronic devices. Nearly all electronic devices include either a battery or a power supply that is capable of drawing power from another power source. Some electronic devices include both a battery and a power supply. Increasingly, electronic devices include various types of integrated circuits. These integrated circuits range from advanced processors used in computers and other similar types of devices to simple logic circuits used in less sophisticated devices such as toasters or microwaves. All of these integrated circuits require power from some type of power source.

Both batteries and power supplies have disadvantages. Batteries may require recharging or replacement and may be impractical for higher power devices. Power supplies must be directly connected to a power source and thus may be impractical for devices that need to be portable. Both power sources can be expensive depending on the amount of power provided. Batteries can also be expensive to replace.

There are various alternative sources of power. For example, solar panels may be useful in locations with predicable amount of sun. However, the solar panels may require a large surface area to generate sufficient power for high-power devices. Radiation may provide various advantages over batteries, traditional power supplies, solar panels, and other sources. Radiation may provide long lasting power without the need to be connected to a power source. Radiation may require a miniscule amount of fuel to provide enough power for even the most power-hungry devices. This characteristic may result in the amount of space required by a radiation power source to be smaller than the other power sources that provide similar amounts of power.

Harnessing the power of radiation may involve the use of receptors that are configured to receive the radiation and convert the radiation to power that is usable by other types of devices. These types of receptors may be similar to solar cells that receive solar energy and convert that solar energy to power that can then be used by virtually any type of device that consumes electrical power. The solar cell acts as an intermediary between the solar power from the sun and the electrical device. The same intermediary quality may be shared by the receptors that receive the radiation and convert the radiation to electrical power.

In some instances, the radiation receptors may be incorporated into a device. The radiation receptors convert the radiation into electrical power. The device then consumes that electrical power. The device may be unable to function without the radiation receptors providing power or without another energy source. There may not be a part of the device that performs any action or process without receiving power from the radiation receptors. The radiation receptors may be replaced with another energy source and the device may operate in a similar fashion.

In contrast, the computation orbs discussed below may be configured to harness radiation to directly power circuitry that is not connected to a traditional power source. The computation orbs may be configured to capture the emittance of alpha, beta, and/or gamma radiation using voltaic materials that may be configured for the different radiation types. The computation orbs may also be configured to convert the radiation directly to current and store the associated energy in a capacitor.

The computation orbs may also include voltaic materials in a transistor circuit that directly utilize the radiation to power the circuit. The circuit may be configured to perform computational logic as the circuit receives control signals. In other words, the circuit may be an algorithmic logic unit or a central processing unit that is powered by radiation instead of traditional power sources.

The computation orbs may include a radiation source at a center of the orb. The orb may include various layers. An inner layer may include a plurality of transistors that are configured to be powered by the radiation. Another layer may include control circuitry and receptors. The receptors may be configured to convert the radiation to power. The control circuitry may receive the power. The control circuitry may generate control signals for the plurality of transistors in the inner layer according to a process or operation to perform. The plurality of transistors in the inner layer may not receive power from the receptors. The source of power for the plurality of transistors in the inner layer is the radiation source.

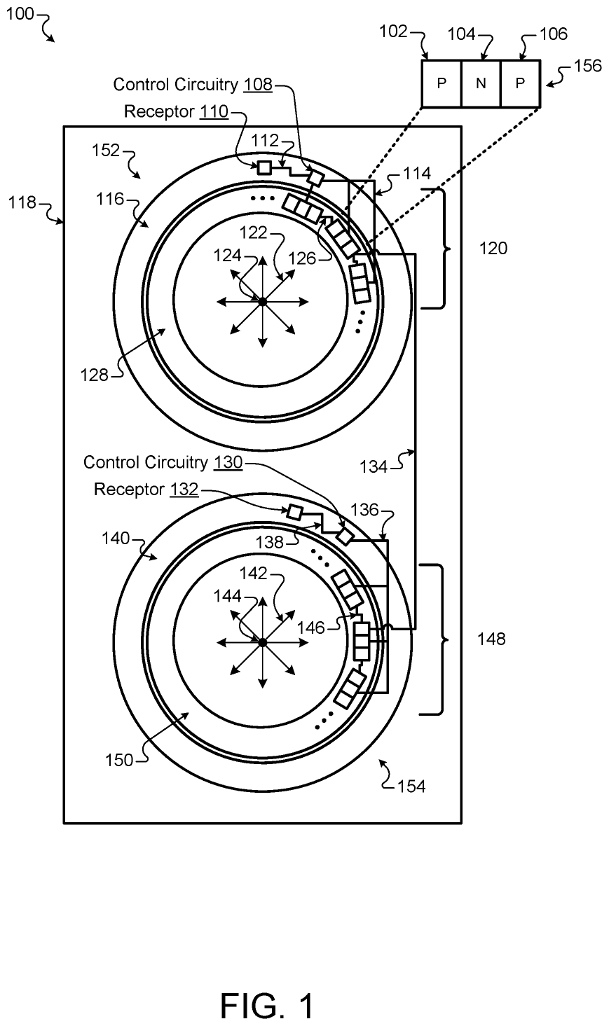

FIG. 1 illustrates an example system 100 that is configured to utilize radiation sources 124, 144 to power groups of transistors 120, 148 that surround the radiation sources 124, 144. Briefly, and as described in more detail below, the groups of transistors 120, 148 may be in the shape of a sphere and surround radiation sources 124, 144. The groups of transistors 120, 148 may receive power from the radiation sources 124, 144 and not be connected to a battery or other type of power source. The groups of transistors 120, 148 may perform operations in response to control signals received from the control circuitry 108, 130. The control circuitry 108, 130 may be powered by the receptors 110, 132 that are configured to convert radiation 122, 142 from the radiation sources 124, 144 to power. The components in FIG. 1 may not be to scale. Additionally, the connections between the components of FIG. 1 may be in different locations than those illustrated.

In more detail, the system 100 may include multiple computation orbs 152, 154. While FIG. 1 may illustrate two computation orbs 152, 154, additional computation orbs may be utilized depending on the computation requirements of the application, the radiation sources 124, 144, and/or any restrictions from the location of the computation orbs. FIG. 1 illustrates a cross section of the computation orbs 152, 154. The computation orbs 152, 154 may be spherical or substantially spherical. In some implementations, the computation orbs 152, 154 may include a hole to allow for placement of the radiation sources 124, 144 into a center of the computation orbs 152, 154. The inner portion of the computation orbs 152, 154 may include a support structure that is configured to maintain the radiation sources 124, 144 at the center of the computation orbs 152, 154. The support structure may also be configured to maintain the structure and shape of the computation orbs 152, 154.

The radiation sources 124, 144 at the center of the computation orbs 152, 154 may emit varying types of radiation. For example, the radiation sources 124, 144 may emit alpha, beta, gamma, and/or any other type of radiation. The radiation 122, 142 emitted by the radiation sources 124, 144 may be emitted at a rate that may decay according to a half-life of the radiation sources 124, 144. In some implementations, the radiation 122, 142 emitted by the radiation sources 124, 144 may increase and decrease at periodic intervals. This increasing and decreasing may be predictable such that the computation orbs 152, 154 may be designed to take advantage of this periodicity. In some implementations, the radiation 122, 142 emitted by the radiation sources 124, 144 may vary depending on a direction from the radiation sources 124, 144. For example, the strength of the radiation 122 at one point on the computation orb 152 may increase and decrease while the strength of the radiation at another point on the computation orb 152 may increase and decrease at similar intervals, opposite intervals (e.g., one increases while the other decreases), and/or unrelated intervals. These increases and decreases may be predicable such that the computation orbs 152, 154 may be designed to take advantage of these changes.

In some implementations, the radiation sources 124, 144 may be byproducts of the processing of various radioactive materials. In some implementations, the radiation sources 124, 144 may be a few atoms each. For example, the radiation sources 124, 144 may be two or three atoms of radioactive material.

The computation orbs 152, 154 may include multiple layers that are configured to capture and utilize the radiation 122, 142 in different ways. For example, the inner layers 128, 150 may include a plurality of transistors 120, 148 that are configured convert the radiation 122, 142 into power. The plurality of transistors 120, 148 may not need to be connected to a power source such as a battery or other voltage source. Instead, the plurality of transistors 120, 148 are powered by the radiation 122, 142.

In some implementations, the plurality of transistors 120, 148 may include bipolar junction transistors. The bipolar junction transistors may be oriented such that the collector, base, and emitter are aligned in a row and are all a similar distance from the radiation source 124, 144. The bipolar transistors may be PNP and/or NPN type transistors. An example transistor 156 of the layer 128 illustrates a PNP type transistor that includes an emitter 102, a base 104, and a collector 106. In some implementations, the emitter 102 and the collector 106 may be flipped.

The plurality of transistors 120, 148 may cover all or most of the layer 128, 150. Some transistors may have a different orientation to other transistors. For example, two transistors may be substantially parallel in that their emitters, bases, and collectors are each a similar distance from each other. As another example, two transistors may be substantially perpendicular. In this case, the emitter of one transistor may be closest to the emitter, base, or collector of the other transistor. The base and the collector may each be progressively farther from the emitter, base, or collector of the other transistor.

In some implementations, the plurality of transistors 120, 148 may be separated by a buffer. The buffer may be configured to absorb, pass, and/or somewhere in between, the radiation 122, 142 that is not utilized by the plurality of transistors 120, 148.

In some implementations, the plurality of transistors 120, 148 may include various electrical connections between each other. The electrical connections may be between transistors on the same computation orb or between transistors of different computation orbs. In some implementations, the layer 128, 150 may be made of silicon or another type of semiconductor and the connections between transistors may be made of metal of another type of conductor derived from the semiconductor material. The electrical connections between transistors of different computation orbs may be made of metal. For example, connection 134 may be a metal connection between a transistor on computation orb 152 and a transistor on computation orb 154.

In some implementations, the distance between the radiation source 124, 144, and the layer 128, 150 may be based on the type of radiation source 124, 144 and/or the type of radiation 122, 142. For example, the stronger the radiation 122, 142, the larger the distance between the radiation source 124, 144, and the layer 128, 150. The strength of the radiation 122, 142 at the layer 128, 150 may be high enough to power the plurality of transistors 120, 148 and benefit any subsequent layers but low enough to avoid damaging or over powering the plurality of transistors 120, 148.

In some implementations, the doping level of the plurality of transistors 120, 148 may be based on the type of radiation source 124, 144, the type of radiation 122, 142, and/or the level of the radiation 122, 142. The doping level of the plurality of transistors 120, 148 may be such that the plurality of transistors 120, 148 are able to operate at a similar level as when powered by a traditional power source. In this case, the doping level may be different than if the plurality of transistors 120, 148 were powered by a traditional power source.

In some implementations, the doping level of the plurality of transistors 120, 148 may vary at different point on the layers 128, 150. For example, if one area of the layer 128 experiences or is expected to receive higher levels of radiation than another area of layer 128, then those two areas of the layer 128 may have different doping levels. As another example, if one area of the layer 128 experiences or is expected to receive a more variable level of radiation than another area of layer 128, then those two areas of the layer 128 may have different doping levels.

In some implementations, the radius of the layers 128, 150 may vary depending on the level of the radiation 122, 142 that different areas experience or are expected to experience. In this case, the computation orb 152, 154 may not be spherical. For example, a portion of the layer 128 that experiences or is expected to experience a higher level of radiation may be farther from the radiation source 124 than a portion of the layer 128 that experiences or is expected to experience a lower level of radiation. In this case, the layer 128 may not be spherical. Instead, the layer 128 may be similar to an ellipsoid, a sphere with an uneven surface, or an ellipsoid with an uneven surface.

The computation orbs 152, 154 may include additional layers. In some implementations, the computation orbs 152, 154 may include an additional layer that is similar to the layers 128, 150. The similar layers may also include transistors that are configured to be powered by the radiation 122, 142. There may be connections between these layers of the same computation orbs and other computation orbs. Some of the radiation 122, 142 may pass through the layers 128, 150. The amount of radiation 122, 142 that passes through the layers 128, 150 may be based on the type of material of the layers 128, 150. That radiation 122, 142 may be received by the layers 116, 140.

In some implementations, the additional layers 116, 140 may include various receptors 110, 132 and control circuitry 108, 130 that are configured to control the inner layers 128, 150. The receptors 110, 132 may be configured to receive the radiation 122, 142 and convert the radiation 122, 142 to power and/or current. The power and/or current may be provided to other portions of the computation orbs 152, 154. The receptors 110, 132 may serve a similar purpose as a battery or other type of power supply.

In some implementations, the receptors 110, 132 may not provide power or current to the plurality of transistors 120, 148. Providing power to the plurality of transistors 120, 148 may not be necessary because the plurality of transistors 120, 148 internally convert the radiation 122, 142 to power.

In some implementations, the receptors 110, 132 may provide the power and/or current to the control circuitry 108, 130 through the electrical connections 112, 138. The electrical connections 112, 138 may be made of a conductive material such as metal.

The control circuitry 108, 130 may be configured to control the plurality of transistors 120, 148 by providing control signals to the plurality of transistors 120, 148. The control circuitry 108, 130 may receive operations, instructions, processes, and/or any other similar action to perform. In response, the control circuitry 108, 130 may generate and provide control signals over connections 114, 136 and other connections between the control circuitry 108, 130 and the plurality of transistors 120, 148. In some implementations, the control circuitry 108, 130 may provide control signals to transistors that are located on a computation orb that is different than the computation orb of the control circuitry.

Although FIG. 1 illustrates a single receptor 110 in computation orb 152 and a single receptor 132 in computation orb 154, the computation orbs 152, 154 may include multiple receptors in the layers 116, 140 and/or other layers. The receptors 110, 132 may be configured to generate power and/or current in response to receiving the radiation 122, 142. The amount of power and/or current generated is related to the amount of radiation 122, 142. In some implementations, the receptors 110, 132 may provide power to the control circuitry 108, 130 and/or to a capacitor for later use by the control circuitry 108, 130 or other components of the computation orbs 152, 154. The control circuitry 108, 130 may not be located at a single location in layers 116, 140 as illustrated in FIG. 1. Instead, portions of the control circuitry 108, 130 may be located throughout the layers 116, 140.

In some implementations, the control signals generated by the control circuitry 108, 130 may be based on an amount of the radiation 122, 142 in addition to or instead of the specified operations. Because the radiation 122, 142 may not be constant, the control circuitry 108, 130 may generate control signals that instruct different portions of the layers 128, 150 to perform an operation depending on the strength of the radiation 122, 142. In one instance, the control circuitry 108, 130 may include radiation detectors that indicate the location and strength of the radiation 122, 142. The control circuitry 108, 130 may compare the location and strength of the radiation 122, 142 to a range where the plurality of transistors 120, 148 operate quickly and accurately. The control circuitry 108, 130 may provide control signals to those locations of the layers 128, 150 where the location and strength of the radiation 122, 142 is within the range. In some implementations, the location and strength of the radiation 122, 142 may be predictable. In this case, the control circuitry 108, 130 may provide control signals to those locations of the layers 128, 150 where the radiation 122, 142 is expected to be within the desired range.

In some implementations, the layers 128, 150 may include some redundancy. In this case, different portions of the layers 128, 150 may be able to perform the same operations and/or processes in response to the same control signals. With this redundancy, the computation orbs 152, 154 may be able to perform the same operations and/or processes even if the location and strength of the radiation 122, 142 is not in a specific location of the layers 128, 150. As an example, if there are two locations in the layer 128 that can perform a sort function and one location is receiving radiation 122 in a desired range and the other location is not receiving radiation 122 in the desired range, then the control circuitry 108, 130 may provide control signals to the location with the radiation 122 in the desired range.

In some implementations, each computation orb 152, 154 may be surrounded by a material that blocks any of the radiation 122, 142 that passes through both the first layer 128, 150 and the second layer 116, 140. As illustrated in FIG. 1, this material 118 may surround both computation orbs 152, 154. In another example, each computation orb 152, 154 may have a material around it that can block any of the radiation 122, 142 that passes through both the first layer 128, 150 and the second layer 116, 140. The material may be lead or any other material that is capable of blocking radiation.

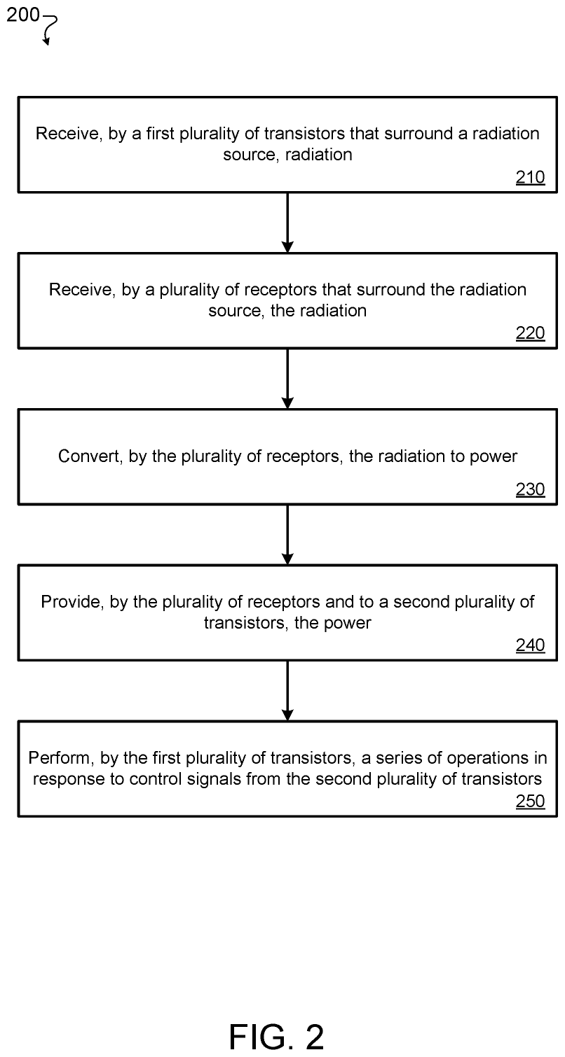

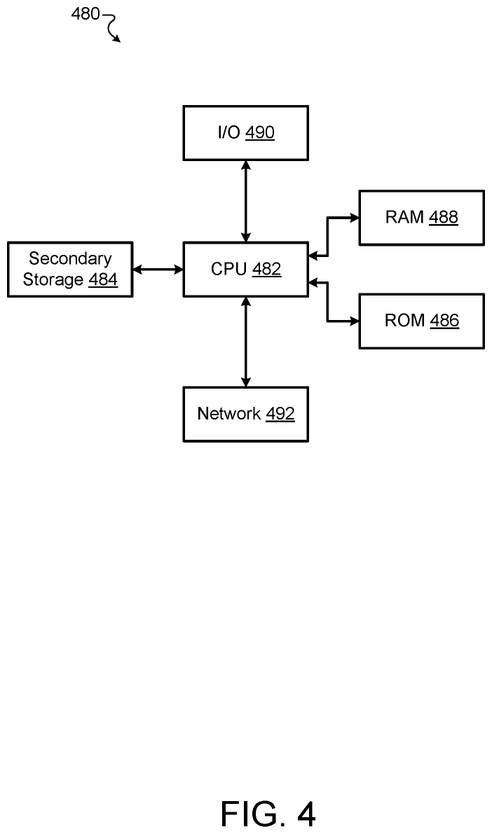

FIG. 2 is a flowchart of an example process 200 for utilizing a radiation source to power a group of transistors that surround the radiation source. In general, the process 200 uses radiation from a radiation source to power a plurality of transistors. The process 200 may use a group of receptors to generate current to power control circuitry. The control circuitry provides control signals to the plurality of transistors for the plurality of transistors to perform various operations and execute instructions. The process 200 will be described as being performed by the system 100 of FIG. 1 and will include references to other components in FIG. 1. The process 200 may be performed by a single system similar to the system 100 or by multiple systems similar to the system 100. In some implementations, the system 100 may be integrated into the computer system 480 of FIG. 4 described below.

A first plurality of transistors 120 that surround a radiation source 124 receives radiation 122 (210). In some implementations, the first plurality of transistors 120 may include bipolar junction transistors, metal-oxide semiconductor field effect transistors, field effect transistors, and/or any combination of these. In some implementations, the radiation 122 is electromagnetic radiation such as gamma radiation. In some implementations, the radiation 122 may be particle radiation such as alpha or beta radiation.

In some implementations, the first plurality of transistors 120 are included in a spherical, or substantially spherical, layer 128 that surrounds the radiation source 124. In some implementations, the radiation source 124 is at a center of the layer 128. In some implementations, the radius of the layer 128 may be based on the type, strength, half-life, and/or any other similar characteristic of the radiation source 124. In some implementations, the radius of the layer 128 may vary such that the layer 128 is not spherical. Instead, the layer 128 may be spherical with points of a larger and smaller radius than the rest of the layer 128.

In some implementations, the doping level of the first plurality of transistors 120 may be based on the type, strength, half-life, and/or any other similar characteristic of the radiation source 124. In some implementations, different transistors in the plurality of transistors 120 may have different doping levels based on the expected type, strength, half-life, and/or any other similar characteristic of the radiation source 124 for that portion of the layer 128.

In some implementations, the first plurality of transistors 120 may not be electrically connected to a battery, voltage source, current source, or other type of traditional power source. In this case, the collectors, emitters, and/or bases and/or drains, sources, and/or gates of the first plurality of transistors 120 may be unconnected to a traditional power source. The first plurality of transistors 120 may instead be powered by the radiation 122.

In some implementations, the orientation of at least some of the transistors of the first plurality of transistors 120 may be such that they are parallel to a tangent of the layer 128. There may be an imaginary axis that passes through the collector, base, emitter, another portion of the base, and another portion of the collector. The axis may be perpendicular to the direction of the radiation 122 and may be parallel to a surface of the transistor. Additionally, or alternatively, there may be an imaginary axis that passes through the drain, the depletion region below the gate, and source. The axis may be perpendicular to the direction of the radiation 122 and may be parallel to a surface of the transistor.

A plurality of receptors 110 that surround the radiation source 124 receives the radiation (220). The plurality of receptors converts the radiation to power (230). The plurality of receptors 110 may be located in a second layer 116 that surrounds the radiation source 124 and the first layer 128. In some implementations, the plurality of receptors may store the power in one or more capacitors.

The plurality of receptors provide, to a second plurality of transistors, the power (240). In some implementations, the one or more capacitors may provide the stored power to the second plurality of transistors. The second plurality of transistors may be included in the second layer 116 with the receptors. In some implementations, the second plurality of transistors are electrically connected to the receptors and/or the capacitors such that they receive power from the receptors and/or the capacitors. In some implementations, the amount of radiation 122 that passes through the first layer 128 to the second layer 116 is based on the type of material included in at least a portion of the first layer 128.

The first plurality of transistors 120 perform a series of operations in response to control signals from the second plurality of transistors 108 (250). In some implementations, the second plurality of transistors 108 control the first plurality of transistors 120 according to an amount of radiation 122 experienced or expected to be experienced by the second plurality of transistors 108. In some implementations, the second plurality of transistors 108 are configured to control the first plurality of transistors 120 by applying voltage to gates or bases or other terminals of each of the first plurality of transistors 120.

In some implementations, the second plurality of transistors 108 are configured to control the first plurality of transistors 120 according to predicted patterns of the radiation 122. The predicted patterns of the radiation 122 may be based on the radiation source 124, the half-life, and/or other characteristics of the radiation 122.

In some implementations, process 200 may involve another radiation source 144 that is surrounded by a first layer 150 and a second layer 140. The first layer 150 may include a first group of transistors 148. The second layer 140 may include receptors 132 and a second group of transistors 130. There may be electrical connections between the first layer 128 and the first layer 150 and/or the second layer 140. There may be electrical connections between the second layer 116 and the first layer 150 and/or the second layer 140.

In some implementations, a third layer 118 may surround the second layers 116 and 140. In some implementations, individual layers may separately surround the second layer 116 and the second layer 140. In some implementations, the third layer 118 may be made of lead or another type of material that is configured to block any radiation 122, 142 that may pass through the second layers 116, 140.

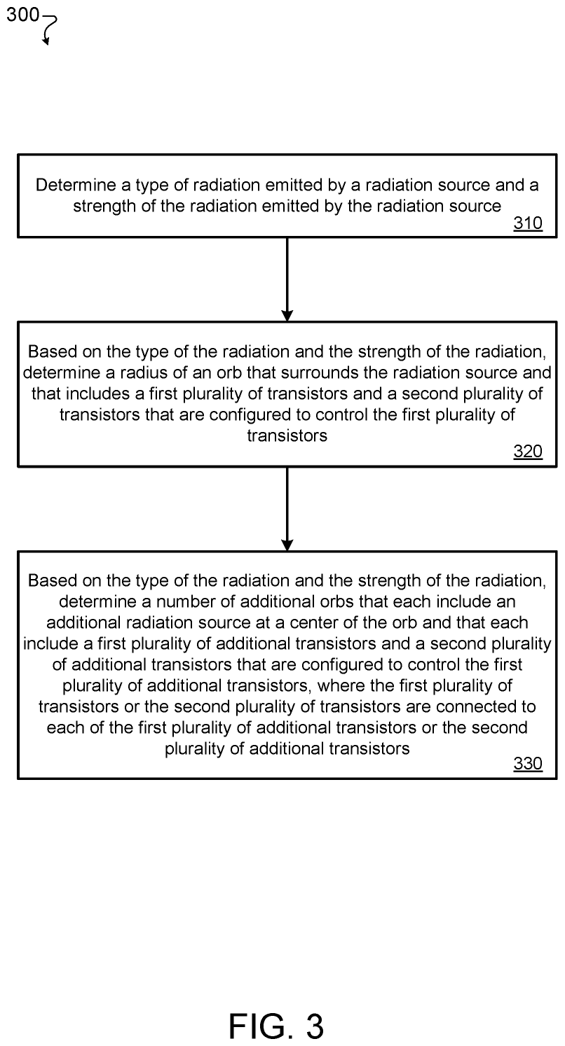

FIG. 3 is a flowchart of an example process 300 for determining a number and size of computation orbs to surround radiation sources based on the characteristics of the radiation sources. In general, the process 300 determines characteristics of a radiation source such as the strength, half-life, and type of radiation. Based on these characteristics, the process 300 determines characteristics of computation orbs to surround the radiation source and leverage the radiation. The process 300 may involve components similar to those in the system 100 of FIG. 1. The process 300 may be performed by a single computing device or split across multiple computing device that may include virtual devices. In some implementations, the process 300 may be performed by the computer system 480 of FIG. 4 described below.

The system determines a type of radiation emitted by a radiation source and a strength of the radiation emitted by the radiation source (310). In some implementations, the type of radiation may be electromagnetic radiation and/or particle radiation. In some implementations, the radiation may vary in a predictable manner.

Based on the type of the radiation and the strength of the radiation, the system determines a radius of an orb that surrounds the radiation source and that includes a first plurality of transistors and a second plurality of transistors that are configured to control the first plurality of transistors (320). The orb may be configured to perform computations, operations, and/or instructions. The orb may not require an external power supply.

Based on the type of the radiation and the strength of the radiation, the system determines a number of additional orbs that each include an additional radiation source at a center of the orb and that each include a first plurality of additional transistors and a second plurality of additional transistors that are configured to control the first plurality of additional transistors (330). In some implementations, the first plurality of transistors or the second plurality of transistors are connected to each of the first plurality of additional transistors or the second plurality of additional transistors. In some implementations, the system may also factor in the computations, operations, and/or instructions that the orbs are tasked with performing. In some implementations, the system may have access to a plurality of computation orbs. The system may activate and deactivate them automatically based on the computations, operations, and/or instructions that need to be performed during the next period. For example, if an upcoming computation is complex or requires circuitry that is located on a specific computation orb, then the system can activate the necessary computation orbs and deactivate the other computation orbs. In some implementations, activating the computation orb can include instructing the receptors to provide power to the control circuitry. Deactivating the computation orb can include instructing the receptors to provide power to capacitors for later use.

FIG. 4 illustrates an example computer system 480 suitable for implementing one or more implementations disclosed herein. The computer system 480 includes a processor 482 (which may be referred to as a central processor unit or CPU) that is in communication with memory devices including secondary storage 484, read only memory (ROM) 486, random access memory (RAM) 488, input/output (I/O) devices 490, and network connectivity devices 492. The processor 482 may be implemented as one or more CPU chips. In some implementations, one or more of the components may be replaced by the system 100. In some instances, this may negate the need for a dedicated power source.

It is understood that by programming and/or loading executable instructions onto the computer system 480, at least one of the CPU 482, the RAM 488, and the ROM 486 are changed, transforming the computer system 480 in part into a particular machine or apparatus having the novel functionality taught by the present disclosure. It is fundamental to the electrical engineering and software engineering arts that functionality that can be implemented by loading executable software into a computer can be converted to a hardware implementation by well-known design rules. Decisions between implementing a concept in software versus hardware typically hinge on considerations of stability of the design and numbers of units to be produced rather than any issues involved in translating from the software domain to the hardware domain. Generally, a design that is still subject to frequent change may be preferred to be implemented in software, because re-spinning a hardware implementation is more expensive than re-spinning a software design. Generally, a design that is stable that will be produced in large volume may be preferred to be implemented in hardware, for example in an application specific integrated circuit (ASIC), because for large production runs the hardware implementation may be less expensive than the software implementation. Often a design may be developed and tested in a software form and later transformed, by well-known design rules, to an equivalent hardware implementation in an application specific integrated circuit that hardwires the instructions of the software. In the same manner as a machine controlled by a new ASIC is a particular machine or apparatus, likewise a computer that has been programmed and/or loaded with executable instructions may be viewed as a particular machine or apparatus.

Additionally, after the system 480 is turned on or booted, the CPU 482 may execute a computer program or application. For example, the CPU 482 may execute software or firmware stored in the ROM 486 or stored in the RAM 488. In some cases, on boot and/or when the application is initiated, the CPU 482 may copy the application or portions of the application from the secondary storage 484 to the RAM 488 or to memory space within the CPU 482 itself, and the CPU 482 may then execute instructions that the application is comprised of. In some cases, the CPU 482 may copy the application or portions of the application from memory accessed via the network connectivity devices 492 or via the I/O devices 490 to the RAM 488 or to memory space within the CPU 482, and the CPU 482 may then execute instructions that the application is comprised of. During execution, an application may load instructions into the CPU 482, for example load some of the instructions of the application into a cache of the CPU 482. In some contexts, an application that is executed may be said to configure the CPU 482 to do something, e.g., to configure the CPU 482 to perform the function or functions promoted by the subject application. When the CPU 482 is configured in this way by the application, the CPU 482 becomes a specific purpose computer or a specific purpose machine.

The secondary storage 484 is typically comprised of one or more disk drives or tape drives and is used for non-volatile storage of data and as an over-flow data storage device if RAM 488 is not large enough to hold all working data. Secondary storage 484 may be used to store programs which are loaded into RAM 488 when such programs are selected for execution. The ROM 486 is used to store instructions and perhaps data which are read during program execution. ROM 486 is a non-volatile memory device which typically has a small memory capacity relative to the larger memory capacity of secondary storage 484. The RAM 488 is used to store volatile data and perhaps to store instructions. Access to both ROM 486 and RAM 488 is typically faster than to secondary storage 484. The secondary storage 484, the RAM 488, and/or the ROM 486 may be referred to in some contexts as computer readable storage media and/or non-transitory computer readable media.

I/O devices 490 may include printers, video monitors, liquid crystal displays (LCDs), touch screen displays, keyboards, keypads, switches, dials, mice, track balls, voice recognizers, card readers, paper tape readers, or other well-known input devices.

The network connectivity devices 492 may take the form of modems, modem banks, Ethernet cards, universal serial bus (USB) interface cards, serial interfaces, token ring cards, fiber distributed data interface (FDDI) cards, wireless local area network (WLAN) cards, radio transceiver cards, and/or other well-known network devices. The network connectivity devices 492 may provide wired communication links and/or wireless communication links (e.g., a first network connectivity device 492 may provide a wired communication link and a second network connectivity device 492 may provide a wireless communication link). Wired communication links may be provided in accordance with Ethernet (IEEE 802.3), Internet protocol (IP), time division multiplex (TDM), data over cable service interface specification (DOCSIS), wavelength division multiplexing (WDM), and/or the like. In some implementations, the radio transceiver cards may provide wireless communication links using protocols such as code division multiple access (CDMA), global system for mobile communications (GSM), long-term evolution (LTE), WiFi (IEEE 802.11), Bluetooth, Zigbee, narrowband Internet of things (NB IoT), near field communications (NFC), radio frequency identity (RFID). The radio transceiver cards may promote radio communications using 5G, 5G New Radio, or 5G LTE radio communication protocols. These network connectivity devices 492 may enable the processor 482 to communicate with the Internet or one or more intranets. With such a network connection, it is contemplated that the processor 482 might receive information from the network, or might output information to the network in the course of performing the above-described method steps. Such information, which is often represented as a sequence of instructions to be executed using processor 482, may be received from and outputted to the network, for example, in the form of a computer data signal embodied in a carrier wave.

Such information, which may include data or instructions to be executed using processor 482 for example, may be received from and outputted to the network, for example, in the form of a computer data baseband signal or signal embodied in a carrier wave. The baseband signal or signal embedded in the carrier wave, or other types of signals currently used or hereafter developed, may be generated according to several methods well-known to one skilled in the art. The baseband signal and/or signal embedded in the carrier wave may be referred to in some contexts as a transitory signal.

The processor 482 executes instructions, codes, computer programs, scripts which it accesses from hard disk, floppy disk, optical disk (these various disk-based systems may all be considered secondary storage 484), flash drive, ROM 486, RAM 488, or the network connectivity devices 492. While only one processor 482 is shown, multiple processors may be present. Thus, while instructions may be discussed as executed by a processor, the instructions may be executed simultaneously, serially, or otherwise executed by one or multiple processors. Instructions, codes, computer programs, scripts, and/or data that may be accessed from the secondary storage 484, for example, hard drives, floppy disks, optical disks, and/or other device, the ROM 486, and/or the RAM 488 may be referred to in some contexts as non-transitory instructions and/or non-transitory information.

In some implementations, the computer system 480 may comprise two or more computers in communication with each other that collaborate to perform a task. For example, but not by way of limitation, an application may be partitioned in such a way as to permit concurrent and/or parallel processing of the instructions of the application. Alternatively, the data processed by the application may be partitioned in such a way as to permit concurrent and/or parallel processing of different portions of a data set by the two or more computers. In some implementations, virtualization software may be employed by the computer system 480 to provide the functionality of a number of servers that is not directly bound to the number of computers in the computer system 480. For example, virtualization software may provide twenty virtual servers on four physical computers. In some implementations, the functionality disclosed above may be provided by executing the application and/or applications in a cloud computing environment. Cloud computing may comprise providing computing services via a network connection using dynamically scalable computing resources. Cloud computing may be supported, at least in part, by virtualization software. A cloud computing environment may be established by an enterprise and/or may be hired on an as-needed basis from a third-party provider. Some cloud computing environments may comprise cloud computing resources owned and operated by the enterprise as well as cloud computing resources hired and/or leased from a third-party provider.

In some implementations, some or all of the functionality disclosed above may be provided as a computer program product. The computer program product may comprise one or more computer readable storage medium having computer usable program code embodied therein to implement the functionality disclosed above. The computer program product may comprise data structures, executable instructions, and other computer usable program code. The computer program product may be embodied in removable computer storage media and/or non-removable computer storage media. The removable computer readable storage medium may comprise, without limitation, a paper tape, a magnetic tape, magnetic disk, an optical disk, a solid state memory chip, for example analog magnetic tape, compact disk read only memory (CD-ROM) disks, floppy disks, jump drives, digital cards, multimedia cards, and others. The computer program product may be suitable for loading, by the computer system 480, at least portions of the contents of the computer program product to the secondary storage 484, to the ROM 486, to the RAM 488, and/or to other non-volatile memory and volatile memory of the computer system 480. The processor 482 may process the executable instructions and/or data structures in part by directly accessing the computer program product, for example by reading from a CD-ROM disk inserted into a disk drive peripheral of the computer system 480. Alternatively, the processor 482 may process the executable instructions and/or data structures by remotely accessing the computer program product, for example by downloading the executable instructions and/or data structures from a remote server through the network connectivity devices 492. The computer program product may comprise instructions that promote the loading and/or copying of data, data structures, files, and/or executable instructions to the secondary storage 484, to the ROM 486, to the RAM 488, and/or to other non-volatile memory and volatile memory of the computer system 480.

In some contexts, the secondary storage 484, the ROM 486, and the RAM 488 may be referred to as a non-transitory computer readable medium or a computer readable storage media. A dynamic RAM implementation of the RAM 488, likewise, may be referred to as a non-transitory computer readable medium in that while the dynamic RAM receives electrical power and is operated in accordance with its design, for example during a period of time during which the computer system 480 is turned on and operational, the dynamic RAM stores information that is written to it. Similarly, the processor 482 may comprise an internal RAM, an internal ROM, a cache memory, and/or other internal non-transitory storage blocks, sections, or components that may be referred to in some contexts as non-transitory computer readable media or computer readable storage media.

While several implementations have been provided in the present disclosure, it should be understood that the disclosed systems and methods may be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted or not implemented.

Also, techniques, systems, subsystems, and methods described and illustrated in the various implementations as discrete or separate may be combined or integrated with other systems, modules, techniques, or methods without departing from the scope of the present disclosure. Other items shown or discussed as directly coupled or communicating with each other may be indirectly coupled or communicating through some interface, device, or intermediate component, whether electrically, mechanically, or otherwise. Other examples of changes, substitutions, and alterations are ascertainable by one skilled in the art and could be made without departing from the spirit and scope disclosed herein.

What is claimed is:

1. A method comprising:
determining a type of radiation emitted by a radiation source and a strength of the radiation emitted by the radiation source;
based on the type of the radiation and the strength of the radiation, determining a radius of an orb that surrounds the radiation source and that includes a first plurality of transistors and a second plurality of transistors that are configured to control the first plurality of transistors; and
based on the type of the radiation and the strength of the radiation, determining a number of additional orbs that each include an additional radiation source at a center of the orb and that each include a first plurality of additional transistors and a second plurality of additional transistors that are configured to control the first plurality of additional transistors,
wherein the first plurality of transistors or the second plurality of transistors are connected to each of the first plurality of additional transistors or the second plurality of additional transistors.

2. The method of claim 1, comprising:
determining computations, operations, or instructions to be performed by the orb and the additional orbs,
wherein determining the number of additional orbs is further based on the computations, the operations, or the instructions to be performed by the orb and the additional orbs.

3. The method of claim 1, wherein the orb and the additional orbs are configured to activate or deactivate based on computations, operations, or instructions being performed by the orb and the additional orbs.

4. The method of claim 1, wherein:
the orb includes receptors that are configured to generate power and provide the power to the second plurality of transistors based on the orb being activated or provide the power to capacitors based on the orb being deactivated, and
the additional orbs each include additional receptors that are configured to generate additional power and provide the additional power to the second plurality of additional transistors based on the additional orb being activated or provide the additional power to additional capacitors based on the additional orb being deactivated.

5. A method comprising:
receiving, by a first plurality of transistors that surround a radiation source, radiation;
receiving, by a plurality of receptors that surround the radiation source, the radiation;
converting, by the plurality of receptors, the radiation to power;
providing, by the plurality of receptors and to a second plurality of transistors, the power; and
performing, by the first plurality of transistors, a series of operations in response to control signals from the second plurality of transistors.

6. The method of claim 5, wherein the radiation is beta radiation.

7. The method of claim 5, wherein the first plurality of transistors are bipolar junction transistors.

8. The method of claim 5, wherein a doping level of the first plurality of transistors is determined based on a type of the radiation emitted by the radiation source.

9. The method of claim 5, wherein the second plurality of transistors are configured to control the first plurality of transistors according to predicted patterns of the radiation.

10. An apparatus comprising:
a radiation source that is configured to emit radiation;
a first layer that surrounds the radiation source and that includes:
a first plurality of transistors that are configured to be powered by the radiation; and
a second layer that surrounds the first layer and that includes:
a plurality of receptors that are configured to convert the radiation to power; and
a second plurality of transistors that receive the power and that are configured control the first plurality of transistors.

11. The apparatus of claim 10, wherein:
a distance between the radiation source and the first layer is a fixed radius, and
the fixed radius is based on the radiation source.

12. The apparatus of claim 10, wherein an axis that intersects a center of an emitter, a base, and a collector of a transistor of the first plurality of transistors is perpendicular to a direction of travel of the radiation.

13. The apparatus of claim 10, comprising:
a third layer that surrounds the second layer and that is configured to block the radiation.

14. The apparatus of claim 10, wherein:
the first layer and the second layer are spherical, and
the radiation source is at a center of both the first layer and the second layer.

15. The apparatus of claim 10, wherein the second plurality of transistors are configured to control the first plurality of transistors (i) according to an operation to be executed by the first plurality of transistors, (ii) according to an amount of the radiation generated by the radiation source, or (iii) by applying voltage to gates or bases of each of the first plurality of transistors.

16. The apparatus of claim 10, wherein:
a first amount of the radiation that passes through portions of the first layer that is between transistors of the plurality of transistors is based on a type of material in the portions of the first layer, and
a second amount of the radiation that passes through the transistors of the first plurality of transistors is based on control signals received from the second plurality of transistors.

17. The apparatus of claim 10, wherein collectors and emitters of transistors in the first plurality of transistors are electrically unconnected to a power source.

18. The apparatus of claim 10, comprising:
an additional radiation source that is configured to emit additional radiation;
an additional first layer that surrounds the additional radiation source and that includes:
a first additional plurality of transistors that are configured to be powered by the additional radiation and that are electrically connected to the first plurality of transistors or the second plurality of transistors; and
an additional second layer that surrounds the additional first layer and that includes:
an additional plurality of receptors that are configured to convert the additional radiation to additional power; and
a second additional plurality of transistors that receive the additional power, that are configured control the first additional plurality of transistors, and that are electrically connected to the first plurality of transistors or the second plurality of transistors.

19. The apparatus of claim 10, wherein the first plurality of transistors are electrically connected to the second plurality of transistors.

20. The apparatus of claim 10, comprising:
a capacitor that is configured to store the power generated by the plurality of receptors and provide the stored power to the second plurality of transistors.
